(19) United States
(12) Patent Application Publication
(10) Pub. No.: US 2012/0175159 A1
(43) Pub. Date: Jul. 12, 2012

(54) RESIN COMPOSITION FOR USE IN RELEASE FILM

(75) Inventors: Hiroyuki SAKAUCHI, Kawasaki-shi (JP); Hiroshi Orikabe, Kawasaki-shi (JP)

(73) Assignee: AJINOMOTO CO. INC, Tokyo (JP)

(21) Appl. No.: 13/344,792

(22) Filed: Jan. 6, 2012

(30) Foreign Application Priority Data
Jan. 7, 2011 (JP) 2011/002521

(51) Int. Cl. H05K 1/00; C08K 3/22; B32B 38/10; C08L 63/00

(52) U.S. Cl. 174/258; 523/457; 523/440; 156/249

(57) ABSTRACT

By incorporating an epoxy resin and aluminum hydroxide into a resin composition, it is possible to achieve a resin composition for use in a release film, which retains high bond strength after a build-up layer is cured, and which has excellent peel strength after being subjected to heating treatment for releasing.

### CROSS REFERENCES TO RELATED APPLICATIONS

This application claims priority to Japanese Patent Application No. 002521/2011, filed on Jan. 7, 2011, which is incorporated herein by reference in its entirety.

### BACKGROUND OF THE INVENTION

1. Field of the Invention

The present invention relates to resin compositions which are useful as release films and which have a specific formulation.

2. Discussion of the Background

In recent years, as electronic devices are reduced in size and improved in performance, electronic parts for the devices, such as IC chips and LSIs, are being rapidly increased in density and integration degree, and substrates for them are required to have an increased wiring density and increased terminals.

JP-A-2005-243999 discloses a method for producing a coreless substrate having a heat releasable bonding layer as an example of a method for increasing the wiring density of a substrate. However, the bonding layer in the substrate produced by this method cannot achieve satisfactory bonding properties at a laminate curing temperature.

Thus, there remains a need for improved methods and materials for producing such devices.

### SUMMARY OF THE INVENTION

Accordingly, it is one object of the present invention to provide novel resin compositions for use in release films.

It is another object of the present invention to provide novel resin compositions for use in release films, which retain a high bond strength after a build-up layer is cured, and which has excellent peel strength after being subjected to heating treatment for releasing.

It is another object of the present invention to provide novel release films which comprising such a resin composition.

It is another object of the present invention to provide novel methods for preparing a circuit board by using such a resin composition or release film.

It is another object of the present invention to provide novel circuit boards which are prepared by such a method.

These and other objects, which will become apparent during the following detailed description, have been achieved by the inventors' discovery that by incorporating an epoxy resin and aluminum hydroxide into a resin composition, improved resin compositions may be obtain.

Thus, the present invention provides:

(1) A resin composition for use in a release film, comprising (A) an epoxy resin and (B) aluminum hydroxide.

(2) The resin composition for use in a release film according to item (1) above, which exhibits a bond strength of 0.25 kgf/cm or more with respect to a metal foil after subjected to heating treatment at 180° C. for 90 minutes five times, and exhibits a peel strength of 0.2 kgf/cm or less with respect to a metal foil after further subjected to heating treatment at 270° C. for 55 seconds five times.

(3) The resin composition for use in a release film according to item (1) or (2) above, which exhibits a bond strength of 0.25 kgf/cm or more with respect to a metal foil after subjected to heating treatment at 180° C. for 90 minutes five times, and exhibits a peel strength of 0.07 kgf/cm or less with respect to a metal foil after further subjected to heating treatment at 270° C. for 55 seconds five times.

(4) The resin composition for use in a release film according to any one of items (1) to (3) above, wherein the content of the aluminum hydroxide (B) is from 5 to 85% by mass per 100% by mass of the non-volatile component in the resin composition.

(5) The resin composition for use in a release film according to any one of items (1) to (4) above, wherein the aluminum hydroxide (B) has an average particle size of from 0.01 to 5 μm.

(6) The resin composition for use in a release film according to any one of items (1) to (5) above, further comprising (C) a curing agent.

(7) The resin composition for use in a release film according to item (6) above, wherein the curing agent (C) is a phenolic curing agent.

(8) The resin composition for use in a release film according to item (6) or (7) above, wherein when the epoxy group number of the epoxy resin (A) is taken as 1, the reactive functional group number of the curing agent (C) is from 0.05 to 1.

(9) The resin composition for use in a release film according to any one of items (1) to (8) above, further comprising (D) a thermoplastic resin.

(10) The resin composition for use in a release film according to item (9) above, wherein the thermoplastic resin (D) is a modified polyimide resin.

(11) The resin composition for use in a release film according to item (10) above, wherein the modified polyimide resin has in the molecule thereof a polybutadiene structure, an urethane structure, and an imide structure.

(12) The resin composition for use in a release film according to any one of items (1) to (11) above, further comprising (E) a cure accelerator.

(13) A release film comprising the resin composition for use in a release film according to any one of items (1) to (12) above.

(14) A release film having a support, comprising the resin composition for use in a release film according to any one of items (1) to (12) above.

(15) A circuit board which is produced using the resin composition for use in a release film according to any one of items (1) to (12) above.

By incorporating an epoxy resin and aluminum hydroxide into a resin composition, there can be provided a resin composition for use in a release film, which retains high bond strength after a build-up layer is cured, and which has excellent peel strength after subjected to heating treatment for releasing.

### DETAILED DESCRIPTION OF THE PREFERRED EMBODIMENTS

The present invention is directed to a resin composition for use in a release film, which comprises (A) an epoxy resin and (B) aluminum hydroxide. The present invention will be described in detail below.

### (A) Epoxy Resin.

With respect to the epoxy resin (A) used in the present invention, there is no particular limitation, and specifically, examples of epoxy resins include bisphenol A epoxy resins, bisphenol F epoxy resins, bisphenol S epoxy resins, bisphenol AF epoxy resins, phenolic novolak epoxy resins, tert-butylcatechol epoxy resins, naphthalene epoxy resins, dicyclopentadiene epoxy resins, glycidylamine epoxy resins, cresol novolak epoxy resins, biphenyl epoxy resins, linear aliphatic epoxy resins, alicyclic epoxy resins, heterocyclic epoxy resins, spiro ring-containing epoxy resins, cyclohexanedimethanol epoxy resins, trimethylol epoxy resins, and halogenated epoxy resins. Of these, from the viewpoint of improving the initial bond strength, preferred are bisphenol A epoxy resins, bisphenol F epoxy resins, dicyclopentadiene epoxy resins, biphenyl epoxy resins, and naphthalene epoxy resins, and more preferred are bisphenol A epoxy resins and dicyclopentadiene epoxy resins. Preferred examples include a liquid bisphenol A epoxy resin (“jER 828EL”, manufactured by Mitsubishi Chemical Corporation), a naphthalene difunctional epoxy resin (“HP 4032” and “HP 4032D”, manufactured by DIC Corporation), a naphthalene tetrafunctional epoxy resin (“HP 4700” and “HP 4710”, manufactured by DIC Corporation), a naphthol epoxy resin (“ESN-475V”, manufactured by Nippon Steel Chemical Co., Ltd.), an epoxy resin having a butadiene structure (“PB-3600”, manufactured by Daicel Chemical Industries, Ltd.), a dicyclopentadiene epoxy resin (“HP 7200H”, manufactured by DIC Corporation), and a biphenyl epoxy resin (“NC 3000H” and “NC 3000L”, manufactured by Nippon Kayaku Co., Ltd.; and “YX 4000”, manufactured by Mitsubishi Chemical Corporation).

The epoxy resins (A) may be used individually or in combination, but the epoxy resin (A) comprises an epoxy resin having two or more epoxy groups per molecule. It is preferred that at least 50% by mass or more of the epoxy resin (A) is an epoxy resin having two or more epoxy groups per molecule. It is more preferred that the epoxy resin (A) comprises an aromatic epoxy resin, which has two or more epoxy groups per molecule and which is in a liquid state at a temperature of 20° C., and an aromatic epoxy resin, which has three or more epoxy groups per molecule and which is in a solid state at a temperature of 20° C. In the present invention, the aromatic epoxy resin means an epoxy resin having in the molecule thereof an aromatic ring structure. An epoxy equivalent (g/eq) means a value obtained by dividing an average molecular weight by the number of epoxy group(s) per molecule. By using a liquid epoxy resin and a solid epoxy resin in combination as the epoxy resin, the following advantage is obtained. When the resin composition is used in the form of a release film, not only can a release film having satisfactory flexibility such that the film can be handled with ease be formed, but also the resin composition exhibits improved releasability after subjected to heating treatment for releasing.

With respect to the content of the epoxy resin (A) in the resin composition for use in a release film, there is no particular limitation, but, from the viewpoint of causing the resin composition to retain excellent bond strength after subjected to heat treatment for curing, the lower limit of the content of the epoxy resin (A) is preferably 5% by mass or more, more preferably 7% by mass or more, further preferably 9% by mass or more, still further preferably 11% by mass or more, per 100% by mass of the non-volatile component in the resin composition. On the other hand, from the viewpoint of preventing the resin composition for use in release film from becoming brittle, the upper limit of the content of the epoxy resin (A) is preferably 30% by mass or less, more preferably 25% by mass or less, further preferably 20% by mass or less, per 100% by mass of the non-volatile component in the resin composition.

### (B) Aluminum Hydroxide.

Specific examples of the aluminum hydroxide (B) used in the present invention include “H-42S”, “H-435”, and “H-42M”, manufactured by Showa Denko K.K.; “CL 301R” and “CL-303”, manufactured by Sumitomo Chemical Co., Ltd.; “B 703”, “B 703T”, and “B 703S”, manufactured by Nippon Light Metal Co., Ltd.; and “ALH”, manufactured by Kawai Lime Industry Co., Ltd.

With respect to the content of the aluminum hydroxide (B) in the resin composition for use in a release film, there is no particular limitation, but, from the viewpoint of improving the releasability after the heating treatment for releasing, the lower limit of the content of the aluminum hydroxide (B) is preferably 5% by mass or more, more preferably 10% by mass or more, further preferably 20% by mass or more, still further preferably 25% by mass or more, even more preferably 30% by mass or more, particularly preferably 35% by mass or more, especially preferably 40% by mass or more, and still more further preferably 45% by mass or more, per 100% by mass of the non-volatile component in the resin composition. On the other hand, from the viewpoint of surely achieving a bond strength before the heating treatment for releasing, the upper limit of the content of the aluminum hydroxide (B) is preferably 85% by mass or less, more preferably 80% by mass or less, further preferably 75% by mass or less, still further preferably 70% by mass or less, even more preferably 65% by mass or less, and especially preferably 60% by mass or less, per 100% by mass of the non-volatile component in the resin composition.

With respect to an average particle size of the aluminum hydroxide (B), there is no particular limitation, but, from the viewpoint of improving the releasability, the upper limit of the average particle size of the aluminum hydroxide (B) is preferably 5 μm or less, more preferably 4 μm or less, further preferably 3 μm or less, and still further preferably 2 μm or less. On the other hand, from the viewpoint of preventing the viscosity of a resin varnish, which is formed from the resin composition for use in release film, from increasing to decrease the handling properties, the lower limit of the average particle size of the aluminum hydroxide (B) is preferably 0.01 μm or more, more preferably 0.05 μm or more, further preferably 0.1 μm or more, still further preferably 0.3 μm or more, even more preferably 0.4 μm or more, particularly preferably 0.5 μm or more, and especially preferably 1 μm or more.

The average particle size of the aluminum hydroxide can be measured by a laser diffraction and scattering method based on the Mie scattering theory. Specifically, the average particle size can be measured by preparing a particle size distribution of the aluminum hydroxide in terms of the volume by means of a laser diffraction particle size distribution measurement apparatus, and obtaining a median diameter in the distribution as the average particle size of the aluminum hydroxide. As a sample for measurement, a dispersion of the aluminum hydroxide in water formed using ultrasonic waves can be preferably used. As the laser diffraction particle size distribution measurement apparatus, LA-500, manufactured by Horiba, Ltd., or the like can be used.

### (C) Curing Agent.

With respect to the resin composition for use in a release film of the present invention, for the purpose of improving heat resistance, a curing agent (C) can be added to the resin composition. With respect to the curing agent (C) used in the invention, there is no particular limitation, and specific examples of curing agents include a phenolic curing agent, an active ester curing agent, a benzoxazine curing agent, a cyanate ester curing agent, and an acid anhydride curing agent. Of these, from the viewpoint of improving the heat resistance, a phenolic curing agent is preferred. The curing agents (C) can be used individually or in combination.

With respect to the phenolic curing agent, there is no particular limitation, but examples of phenolic curing agents include phenolic novolak resins, triazine skeleton-containing phenolic novolak resins, naphthol novolak resins, naphthol aralkyl resins, triazine skeleton-containing naphthol resins, and biphenyl aralkyl phenolic resins. Examples of biphenyl aralkyl phenolic resins include “MEH-7700”, “MEH-7810”, and “MEH-7851” (manufactured by Meiwa Plastic Industries, Ltd.), and “NHN”, “CBN”, and “GPH” (manufactured by Nippon Kayaku Co., Ltd.), examples of naphthol aralkyl resins include “SN 170”, “SN 180”, “SN 190”, “SN 475”, “SN 485”, “SN 495”, “SN 375”, and “SN 395” (manufactured by Nippon Steel Chemical Co., Ltd.), examples of phenolic novolak resins include “TD 2090” (manufactured by DIC Corporation), and examples of triazine skeleton-containing phenolic novolak resins include “LA 3018”, “LA 7052”, “LA 7054”, and “LA 1356” (manufactured by DIC Corporation). The phenolic curing agents may be used individually or in combination.

With respect to the active ester curing agent, preferred are compounds having two or more highly reactive ester groups per molecule, such as phenol esters, thiophenol esters, N-hydroxyamine esters, and heterocyclic hydroxy compound esters. With respect to the active ester curing agent, preferred is one which is obtained by a condensation reaction of a carboxylic acid compound and/or a thiocarboxylic acid compound and a hydroxy compound and/or a thiol compound. Especially, from the viewpoint of heat resistance and the like, more preferred is an active ester curing agent which is obtained from a carboxylic acid compound and a hydroxy compound, and further preferred is one which is obtained from a carboxylic acid compound and a phenolic compound or a naphthol compound. Examples of carboxylic acid compounds include benzoic acid, acetic acid, succinic acid, maleic acid, itaconic acid, phthalic acid, isophthalic acid, terephthalic acid, and pyromellitic acid. Examples of phenolic compounds or naphthol compounds include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, dicyclopentadienyldiphenol, and phenolic novolak. With respect to the active ester curing agent, the active ester curing agent disclosed in JP-A-2004-427761, which is incorporated herein by reference in its entirety, may be used, or a commercially available active ester curing agent can be used. Examples of commercially available active ester curing agents include those containing a dicyclopentadienyldiphenol structure, such as EXB-9451 and EXB-9460 (manufactured by DIC Corporation), acetylation products of phenolic novolak, such as DC 808 (manufactured by Mitsubishi Chemical Corporation), and benzoyl products of phenolic novolak, such as YLH 1026 (manufactured by Mitsubishi Chemical Corporation). The active ester curing agents may be used individually or in combination.

With respect to the benzoxazine curing agent, there is no particular limitation, but, as specific examples of benzoxazine curing agents, there can be mentioned F-a, P-d (manufactured by Shikoku Chemicals Corporation) and HFB 2006M (manufactured by Showa High Polymer Co., Ltd.).

With respect to the cyanate ester curing agent, there is no particular limitation, but examples of cyanate ester curing agents include a novolak (e.g., phenolic novolak or alkylphenolic novolak) cyanate ester curing agent, a bisphenol (e.g., bisphenol A, bisphenol F, or bisphenol S) cyanate ester curing agent, a dicyclopentadiene cyanate ester curing agent, and a prepolymer obtained by changing part of the above agents to triazine. Specific examples include a phenolic novolak multifunctional cyanate ester curing agent (“PT 30” and “PT 60”, manufactured by Lonza Japan), a prepolymer obtained by changing part of or all of a bisphenol A dicyanate to triazine to form a trimer (“BA 230”, manufactured by Lonza Japan), and a dicyclopentadiene cyanate ester curing agent (“DT-4000” and “DT-7000”, manufactured by Lonza Japan).

With respect to the content of the curing agent (C) in the resin composition for use in a release film, there is no particular limitation, but, from the viewpoint of causing the resin composition to retain excellent bond strength after being subjected to heat treatment for curing, the content of the curing agent (C) is preferably 0.1% by mass or more, more preferably 0.2% by mass or more, further preferably 0.4% by mass or more, and still further preferably 0.6% by mass or more, per 100% by mass of the non-volatile component in the resin composition. On the other hand, from the viewpoint of preventing the cured product from becoming brittle, the content of the curing agent (C) is preferably 20% by mass or less, more preferably 18% by mass or less, further preferably 16% by mass or less, still further preferably 14% by mass or less, even more preferably 12% by mass or less, particularly preferably 10% by mass or less, and especially preferably 8% by mass or less, per 100% by mass of the non-volatile component in the resin composition.

With respect to the ratio of the curing agent (C) to the resin, there is no particular limitation, but, when the epoxy group number of the epoxy resin (A) is taken as 1, the reactive functional group number of the curing agent (C) may be 0, but is preferably 0.05 or more from the viewpoint of improving heat resistance. On the other hand, from the viewpoint of causing the resin composition to retain excellent bond strength after being subjected to heat treatment, when the epoxy group number of the epoxy resin (A) is taken as 1, the reactive functional group number of the curing agent (C) is preferably 1 or less, more preferably 0.9 or less, further preferably 0.8 or less, still further preferably 0.7 or less, even more preferably 0.67 or less, particularly preferably 0.64 or less, and especially preferably 0.61 or less, 0.6 or less, 0.58 or less, 0.56 or less, 0.54 or less, and 0.52 or less in this order. A reactive functional group indicates a functional group capable of reacting with an epoxy group. For example, the reactive functional group indicates a phenolic hydroxyl group in a phenolic curing agent, an active ester group in an active ester curing agent, and a cyanate group in a cyanate curing agent.

### (D) Thermoplastic Resin.

With respect to the resin composition for use in a release film of the present invention, for the purpose of obtaining a release film having increased flexibility such that the handling properties of the film are improved and further a peeled film has excellent appearance of the peel interface, a thermoplastic resin (D) can be added to the resin composition. Examples of such thermoplastic resins include polyimide resins, phenoxy resins, polyamideimide resins, polyether imide resins, polysulfone resins, polyether sulfone resins, polyphenylene ether resins, polycarbonate resins, polyether ether ketone resins, and polyester resins, and, of these, polyimide resins are preferred. These thermoplastic resins may be used individually or in combination. The thermoplastic resin preferably has a weight average molecular weight in the range of from 5,000 to 200,000, more preferably in the range of from 10,000 to 100,000. The weight average molecular weight in the invention is measured by a gel permeation chromatography (GPC) method (polystyrene conversion). In the GPC method, the weight average molecular weight can be determined by measuring a molecular weight using, specifically, LC-9A/RID-6A, manufactured by Shimadzu Corporation, as a measurement apparatus, using Shodex K-800P/K-804L/K-804L, manufactured by Showa Denko K.K., as columns, and using chloroform or the like as a mobile phase at a column temperature of 40° C., and making a calculation from the measured molecular weight using a calibration curve obtained with respect to a standard polystyrene.

Specific examples of polyimide resins include polyimide “RIKACOAT SN 20” and “RIKACOAT PN 20”, manufactured by New Japan Chemical Co., Ltd. Further, examples include a modified polyimide resin having in the molecule thereof a polybutadiene structure, an urethane structure, and an imide structure.

As an example of the modified polyimide resin, there can be mentioned a modified polyimide resin having in the molecule thereof both a polybutadiene structure represented by the formula (1-a) below and an imide structure represented by the formula (1-b) below, and preferred is a modified polyimide resin obtained by reacting three components, i.e., (a) a hydroxyl-terminal polybutadiene, (b) a diisocyanate compound, and (c) a tetrabasic acid dianhydride. From the viewpoint of obtaining a release film having improved flexibility, the content of the polybutadiene structure in the modified polyimide resin is preferably 45% by mass or more, more preferably 60% by mass or more. The content (% by mass) of a polybutadiene structure portion in the modified polyimide resin can be defined as a ratio of the mass of the component (a) to the total mass of the above three components (a) to (c) used in the reaction.

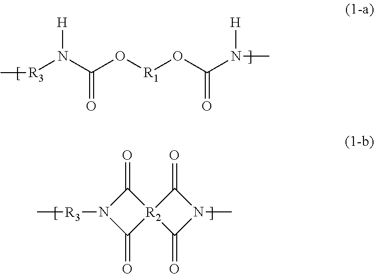

In the above formulae, R1 represents a residue of the hydroxyl-terminal polybutadiene, excluding a hydroxyl groups, R2 represents a residue of the tetrabasic acid dianhydride, excluding an acid anhydride groups, and R3 represents a residue of the diisocyanate compound, excluding an isocyanate groups. With respect to the hydroxyl-terminal polybutadiene, a hydroxyl-terminal polybutadiene having a number average molecular weight of from 800 to 10,000 is preferred. With respect to the polybutadiene structure of the formula (1-a) above, preferred is a polybutadiene structure of the formula (1-a) wherein R1 represents a residue of the hydroxyl-terminal polybutadiene having a number average molecular weight of from 800 to 10,000, excluding the hydroxyl groups. When the number average molecular weight of the hydroxyl-terminal polybutadiene is less than 800, the modified polyimide resin tends to be poor in flexibility. When the number average molecular weight of the hydroxyl-terminal polybutadiene is more than 10,000, the modified polyimide resin tends to be poor in the compatibility with a thermosetting resin and further tends to be poor in heat resistance. In the present invention, the number average molecular weight is a value measured by a gel permeation chromatography (GPC) method (polystyrene conversion). In the GPC method, the number average molecular weight can be determined by measuring a molecular weight using, specifically, LC-9A/RID-6A, manufactured by Shimadzu Corporation, as a measurement apparatus, using Shodex K-800P/K-804L/K-804L, manufactured by Showa Denko K.K., as columns, and using chloroform as a mobile phase at a column temperature of 40° C., and making a calculation from the measured molecular weight using a calibration curve obtained with respect to a standard polystyrene.

The number of the polybutadiene structure(s) (1-a) present in the modified polyimide resin per molecule is from 1 to 10,000, preferably from 1 to 100. The number of the imide structure(s) (1-b) present in the modified polyimide resin per molecule is from 1 to 100, preferably from 1 to 10.

The components (a) to (c) used as raw materials for the modified polyimide resin can be respectively represented by the following formulae (a) to (c).

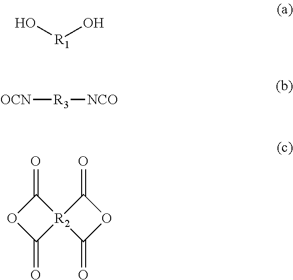

Symbols for substitutes shown in the above formulae are as defined above. The modified polyimide resin can be further modified by a reaction with (d) an additional component.

As an example of a method for producing the modified polyimide resin in the invention, there can be mentioned the following procedure. First, a polybutadiene as the component (a) and a diisocyanate compound as the component (b) are reacted with each other in a ratio such that the functional equivalent of the isocyanate group of the diisocyanate compound to the hydroxyl group of the polybutadiene is more than 1 to obtain a reaction product of the polybutadiene and diisocyanate. The reaction product can be represented by the following formula (a-b).

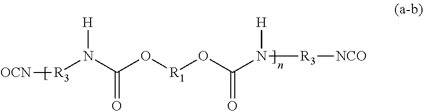

In the above formula, R1 represents a residue of the hydroxyl-terminal polybutadiene, excluding the hydroxyl groups, R3 represents a residue of the diisocyanate compound, excluding the isocyanate groups, and n represents an integer of from 1 to 100 (1≦n≦100). n preferably represents an integer of from 1 to 10 (1≦n≦10). With respect to the reaction product represented by the formula (a-b) above, preferred is a reaction product of the formula (a-b) wherein R1 represents a residue of the hydroxyl-terminal polybutadiene having a number average molecular weight of from 800 to 10,000, excluding the hydroxyl groups.

With respect to the reaction ratio between the polybutadiene and the diisocyanate compound, a reaction is preferably conducted in a ratio such that when the functional equivalent of the hydroxyl group of the polybutadiene is taken as 1, the functional equivalent of the isocyanate group of the diisocyanate compound is from 1.5 to 2.5.

Then, a tetrabasic acid dianhydride is reacted with the reaction product of the polybutadiene and diisocyanate. With respect to the reaction ratio of the tetrabasic acid dianhydride, there is no particular limitation, but it is preferred that the reaction is conducted so that the amount of the isocyanate group remaining in the composition is as small as possible. The reaction is preferably conducted in a ratio that satisfies the relationship: Y>X−W≧Y/5 (W>0, X>0, Y>0), wherein X is the functional equivalent of the isocyanate group of the diisocyanate compound as a raw material, W is the functional equivalent of the hydroxyl group of the hydroxyl-terminal polybutadiene as a raw material, and Y is the functional equivalent of the acid anhydride group of the tetrabasic acid dianhydride.

The thus obtained modified polyimide resin, as mentioned above, has in the molecule thereof both the polybutadiene structure represented by the formula (1-a) and the imide structure represented by the formula (1-b). With respect to the modified polyimide resin in the invention, preferred is one which is mainly made of a modified polyimide having a structure represented by the following formula (a-b-c).

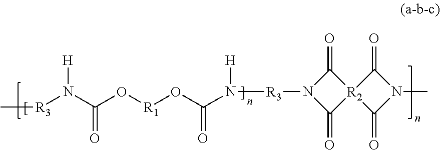

In the above formula, R1 represents a residue of the hydroxyl-terminal polybutadiene, excluding the hydroxyl groups, R2 represents a residue of the tetrabasic acid dianhydride, excluding the acid anhydride groups, R3 represents a residue of the diisocyanate compound, excluding the isocyanate groups, and each of n and m represents an integer of from 1 to 100 (1≦n≦100). Each of n and m preferably represents an integer of from 1 to 10 (1≦n≦10). With respect to the polybutadiene isocyanate represented by the formula (a-b-c) above, preferred is a polybutadiene isocyanate of the formula (a-b-c) wherein R1 represents a residue of the hydroxyl-terminal polybutadiene having a number average molecular weight of from 800 to 10,000, excluding the hydroxyl groups.

For conducting the reaction so that the amount of the isocyanate group remaining in the composition is as small as possible, it is preferred to confirm that the isocyanate group disappears during the reaction using FT-IR or the like. A terminal group of the thus obtained modified polyimide resin can be represented by the following formula (1-c) or (1-d).

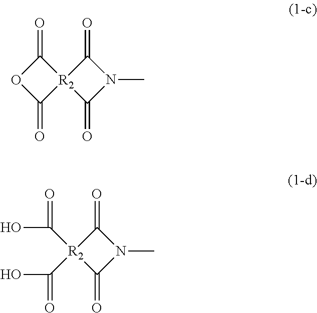

The symbols for groups shown in the above formulae are as defined above.

In the production of a linear modified polyimide resin, a reaction product of the polybutadiene and diisocyanate is reacted with a tetrabasic acid dianhydride, and then the resultant reaction product is further reacted with a diisocyanate compound, thus obtaining a composition containing a linear modified polyimide resin having a higher molecular weight. In this case, with respect to the reaction ratio of the isocyanate compound, there is no particular limitation, but the reaction is preferably conducted in a ratio that satisfies the relationship: Y−(X−W)>Z≧0 (W>0, X>0, Y>0, Z>0), wherein X is the isocyanate functional equivalent of the diisocyanate compound as a raw material, W is the hydroxyl functional equivalent of the hydroxyl-terminal polybutadiene as a raw material, Y is the acid anhydride functional equivalent of the tetrabasic acid dianhydride, and Z is the isocyanate functional equivalent of the isocyanate compound further reacted.

The modified polyimide resin has two chemical structure units, i.e., the polybutadiene structure represented by the formula (1-a) above and the imide structure represented by the formula (1-b) above. Typically, for imparting flexibility to a resin composition, a rubber resin, such as a polybutadiene resin, is generally mixed directly into the resin composition, but a nonpolar rubber resin is likely to cause phase separation in a highly polar thermosetting resin composition, and especially when a rubber resin is mixed in a large amount, a stable resin composition is difficult to obtain. Further, it is likely that a resin composition containing a rubber resin cannot achieve satisfactory heat resistance. In contrast, a polyimide resin has a heat resistance, and has high polarity and hence exhibits relatively excellent compatibility with a thermosetting resin composition. The modified polyimide resin has in the molecule both the polyimide structure and the polybutadiene structure which imparts flexibility to the resin, and therefore is a material having excellent properties in respect of both flexibility and heat resistance. Further, the modified polyimide resin has excellent compatibility with a thermosetting resin, and hence is a material suitable for obtaining a stable thermosetting resin composition.

The hydroxyl-terminal polybutadiene {component (a)} as a raw material for the modified polyimide resin may be one in which an unsaturated bond in the molecule is hydrogenated. As specific examples of hydroxyl-terminal polybutadienes, there can be mentioned G-1000, G-3000, GI-1000, and GI-3000 (manufactured by Nippon Soda Co., Ltd.), and R-45 EPI (manufactured by Idemitsu Petrochemical Co., Ltd.).

In the present invention, the number average molecular weight is a value measured by a gel permeation chromatography (GPC) method (polystyrene conversion). In the GPC method, the number average molecular weight can be determined by measuring a molecular weight using, specifically, LC-9A/RID-6A, manufactured by Shimadzu Corporation, as a measurement apparatus, using Shodex K-800P/K-804L/K-804L, manufactured by Showa Denko K.K., as columns, and using chloroform as a mobile phase at a column temperature of 40° C., and making a calculation from the measured molecular weight using a calibration curve obtained with respect to a standard polystyrene.

Examples of diisocyanate compounds {component (b)} as a raw material for the modified polyimide resin include diisocyanates, such as toluene 2,4-diisocyanate, toluene 2,6-diisocyanate, hexamethylene diisocyanate, xylene diisocyanate, diphenylmethane diisocyanate, and isophorone diisocyanate.

Specific examples of tetrabasic acid dianhydrides {component (c)} as a raw material for the modified polyimide resin include pyromellitic dianhydride, benzophenonetetracarboxylic dianhydride, biphenyltetracarboxylic dianhydride, naphthalenetetracarboxylic dianhydride, 5-(2,5-dioxotetrahydrofuryl)-3-methyl-cyclohexene-1,2-dicarboxylic anhydride, diphenyl sulfone 3,3′,4,4′-tetracarboxylic dianhydride, and 1,3,3a,4,5,9b-hexahydro-5-(tetrahydro-2,5-dioxo-3-furanyl)-naphtho[1,2-C]furan-1,3-dione.

In the production of the modified polyimide resin, a reaction of the hydroxyl-terminal polybutadiene and the diisocyanate compound can be conducted in an organic solvent under conditions such that the reaction temperature is 80° C. or lower and the reaction time is 1 to 8 hours. The reaction may be conducted in the presence of a catalyst if necessary. A reaction between the reaction product of the polybutadiene and diisocyanate and a tetrabasic acid dianhydride can be conducted by cooling a solution containing the reaction product of the polybutadiene and diisocyanate obtained after the above reaction to room temperature, and then adding a tetrabasic acid dianhydride to the solution to effect a reaction under conditions such that the reaction temperature is from 120 to 180° C. and the reaction time is from 2 to 24 hours. The reaction is preferably conducted in the presence of a catalyst. An organic solvent may be further added to the above solution. The resultant reaction solution may be subjected to filtration to remove insoluble matter if necessary. Thus, a modified polyimide resin varnish can be obtained. The amount of the solvent in the modified polyimide resin varnish can be controlled by appropriately changing the amount of the solvent used during the reaction, adding a solvent to the varnish after the reaction, or the like. A modified polyimide resin having a higher molecular weight can be obtained by further reacting a diisocyanate with the reaction product obtained after the reaction between the reaction product of the polybutadiene and diisocyanate and the tetrabasic acid dianhydride. In this case, a diisocyanate compound is added dropwise to the reaction product obtained after the reaction between the reaction product of the polybutadiene and diisocyanate and the tetrabasic acid dianhydride to effect a reaction under conditions such that the reaction temperature is from 120 to 180° C. and the reaction time is from 2 to 24 hours.

Examples of organic solvents used in each of the above reactions include polar solvents, such as N,N′-dimethylformamide, N,N′-diethylformamide, N,N′-dimethylacetamide, N,N′-diethylacetamide, dimethyl sulfoxide, diethyl sulfoxide, N-methyl-2-pyrrolidone, tetramethylurea, γ-butyrolactone, cyclohexanone, diglyme, triglyme, Carbitol acetate, propylene glycol monomethyl ether acetate, and propylene glycol monoethyl ether acetate. These solvents may be used individually or in combination. If necessary, an appropriate nonpolar solvent, such as an aromatic hydrocarbon, can be mixed into the above solvent.

Examples of catalysts used in each of the above reactions include tertiary amines, such as tetramethylbutanediamine, benzyldimethylamine, triethanolamine, triethylamine, N,N′-dimethylpiperidine, α-methylbenzyldimethylamine, N-methylmorpholine, and triethylenediamine, and organometallic catalysts, such as dibutyltin dilaurate, dimethyltin dichloride, cobalt naphthenate, and zinc naphthenate. These catalysts may be used individually or in combination. As a catalyst, triethylenediamine is especially preferably used.

As specific examples of phenoxy resins, there can be mentioned FX 280 and FX 293, manufactured by Nippon Steel Chemical Co., Ltd., and YX 8100, YL 6954, YL 6974, YL 7213, YL 6794, YL 7553, and YL 7482, manufactured by Mitsubishi Chemical Corporation.

With respect to the content of the thermoplastic resin (D) in the resin composition for use in a release film, there is no particular limitation, but, from the viewpoint of increasing the release film in flexibility to improve the handling properties, achieving excellent appearance of the peel interface after peeling the release film off, the lower limit of the content of the thermoplastic resin (D) is preferably 1% by mass or more, more preferably 5% by mass or more, further preferably 10% by mass or more, still further preferably 15% by mass or more, and especially preferably 20% by mass or more, per 100% by mass of the non-volatile component in the resin composition. On the other hand, from the viewpoint of preventing the releasability after the heating treatment for releasing from becoming poor, the upper limit of the content of the thermoplastic resin (D) is preferably 60% by mass or less, more preferably 55% by mass or less, and further preferably 50% by mass or less, per 100% by mass of the non-volatile component in the resin composition.

### (E) Cure Accelerator.

With respect to the resin composition for use in a release film of the present invention, for the purpose of causing an epoxy resin and a curing agent to efficiently undergo a reaction, a cure accelerator (E) can be added to the resin composition. With respect to the cure accelerator (E), there is no particular limitation, but examples of cure accelerators include an imidazole cure accelerator, an amine cure accelerator, a guanidine cure accelerator, and epoxy adducts thereof and microcapsules obtained therefrom.

With respect to the imidazole cure accelerator, there is no particular limitation, but examples of imidazole cure accelerators include imidazole compounds, such as 2-methylimidazole, 2-undecylimidazole, 2-heptadecylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid addition product, 2-phenylimidazole isocyanuric acid addition product, 2-phenyl-4,5-dihydroxymethylimidazole, 2-phenyl-4-methyl-5-hydroxymethylimidazole, 2,3-dihydro-1H-pyrrolo[1,2-a]benzimidazole, 1-dodecyl-2-methyl-3-benzylimidazolium chloride, 2-methylimidazoline, and 2-phenylimidazoline, and adducts of an imidazole compound and an epoxy resin. These compounds may be used individually or in combination.

With respect to the content of the cure accelerator (E) in the resin composition for use in a release film, there is no particular limitation, but, from the viewpoint of permitting the cure accelerator to exhibit satisfactory acceleration effect, the lower limit of the content of the cure accelerator (E) is preferably 0.01% by mass or more, more preferably 0.05% by mass or more, and further preferably 0.1% by mass or more, per 100% by mass of the non-volatile component in the resin composition. On the other hand, from the viewpoint of preventing the resin composition for use in release film from decreasing in storage stability, the upper limit of the content of the cure accelerator (E) is preferably 5% by mass or less, more preferably 3% by mass or less, further preferably 1% by mass or less, and still further preferably 0.5% by mass or less, per 100% by mass of the non-volatile component in the resin composition.

### Other Components.

In the resin composition for use in a release film of the present invention, if necessary, other components can be incorporated in such an amount that the effect of the invention is not sacrificed. Examples of other components include thermosetting resins, such as a vinylbenzyl compound, an acrylic compound, a maleimide compound, and a blocked isocyanate compound; inorganic fillers, such as silica and alumina; organic fillers, such as rubber particles, a flame retardant, silicon powder, nylon powder, and fluorine powder; thickeners, such as orben and bentone; silicone, fluorine, or polymer anti-foaming agents or leveling agents; adhesion imparting agents, such as imidazole, thiazole, triazole, or silane coupling agents; colorants, such as phthalocyanine blue, phthalocyanine green, iodine green, disazo yellow, and carbon black; and flame retardants.

With respect to a method for preparing the resin composition for use in a release film of the invention, there is no particular limitation, and, as an example of the method, there can be mentioned a method in which the components to be incorporated and a solvent or the like optionally added are mixed with each other using a rotary mixer or the like.

The resin composition for use in a release film of the present invention is preferably used as a release film, and can be used in the form of a release film having a support. Further, the resin composition can be used in a wide variety of applications that need a resin composition, such as a prepreg, a solder resist, an under-film material, a die bonding material, a semiconductor encapsulation material, a sealing resin, a part buried resin, a circuit board, a laminate, and a multilayer printed wiring board.

### Release Film.

A release film can be produced from the resin composition for use in a release film of the present invention by applying the resin composition in the form of a resin varnish to a substrate to form a layer of the resin composition. Further, the release film preliminarily formed on a support can be laminated onto a substrate. The release film of the present invention can be laminated onto various types of substrates and peeled off by a heating treatment for releasing. Examples of substrates mainly include substrates, such as a glass epoxy substrate, a metal substrate, a polyester substrate, a polyimide substrate, a BT resin substrate, and a thermosetting polyphenylene ether substrate.

### Release Film Having a Support.

The resin composition for use in a release film of the present invention can be preferably used in the form of a release film having a support such that a layer of the resin composition is formed on a support. The release film having a support can be produced in accordance with a method well known by those skilled in the art, for example, a method comprising dissolving the resin composition of the invention in an organic solvent to prepare a resin varnish, and applying the resin varnish to a support and drying the resin varnish by heating, hot-air blow, or the like to remove the organic solvent, forming a layer of the resin composition on the support.

The support serves as a support for a release film being produced, and is ultimately removed. Examples of supports include polyolefins, such as polyethylene and polyvinyl chloride; polyesters, such as polyethylene terephthalate (hereinafter, frequently referred to simply as “PET”) and polyethylene naphthalate; polycarbonate; release paper; and metal foils, such as a copper foil and an aluminum foil. A heat resistant resin, such as polyimide, polyamide, polyamideimide, or a liquid crystalline polymer, can also be used. When a copper foil is used as a support, the copper foil can be removed by etching using an etch solution, such as ferric chloride or cupric chloride. The support may be subjected to mat treatment, corona discharge treatment, or release treatment, but, from the viewpoint of releasability, it is more preferred that the support has been subjected to release treatment. With respect to the thickness of the support, there is no particular limitation, but the thickness of the support is preferably from 10 to 150 μm, more preferably from 25 to 50 μm.

Examples of organic solvents used for preparing a resin varnish include ketones, such as acetone, methyl ethyl ketone, and cyclohexanone; acetates, such as ethyl acetate, butyl acetate, cellosolve acetate, propylene glycol monomethyl ether acetate, and Carbitol acetate; Carbitols, such as cellosolve and butyl Carbitol; aromatic hydrocarbons, such as toluene and xylene; dimethylformamide; dimethylacetamide; and N-methylpyrrolidone. The organic solvents may be used in combination.

With respect to the conditions for drying the resin composition in the form of a resin varnish, there is no particular limitation, but, for permitting the resultant release film to retain lamination properties, it is important that the resin composition being dried is cured to an extent as small as possible. On the other hand, when the resultant release film contains the remaining organic solvent in a large amount, a blister is caused on the release film after being cured, and therefore the resin varnish is dried so that the organic solvent content of the resin composition becomes 5% by mass or less, preferably 3% by mass or less. Specific drying conditions vary depending on the curing properties of the resin composition or the amount of the organic solvent in the resin varnish, but, for example, a resin varnish containing an organic solvent in an amount of from 30 to 60% by mass can be dried at 80 to 120° C. for 3 to 13 minutes. Those skilled in the art can appropriately select preferred drying conditions from a simple experiment.

From the viewpoint of improving the handling properties, the thickness of the resin composition layer is preferably in the range of from 5 to 500 μm, more preferably in the range of from 10 to 200 μm further preferably in the range of from 15 to 150 μm, still further preferably in the range of from 20 to 100 μm. The resin composition layer may be protected by a protective film. Protection by the protective film can prevent a surface of the resin composition layer from suffering adhesion of contaminants or the like or from being scratched. The protective film is removed before lamination of the release film. As a material for the protective film, the same material as that for the support can be used. With respect to the thickness of the protective film, there is no particular limitation, but the thickness is preferably in the range of from 1 to 40 μm.

The release film having a support of the present invention can be preferably laminated onto a substrate using a vacuum laminator. Examples of commercially available vacuum laminators include a vacuum applicator, manufactured by Nichigo-Morton Co., Ltd., a vacuum press laminator, manufactured by Meiki Co., Ltd., a roll dry coater, manufactured by Hitachi Techno-engineering, Ltd., and a vacuum laminator, manufactured by Hitachi AIC Inc.

In lamination of the release film having a support and having a protective film, the protective film is removed, and then the resultant release film having a support is pressed against a substrate while heating and applying a pressure. Conditions for the lamination are preferably such that the release film having a support and a substrate are preheated if necessary, the pressure for pressing is preferably from 1 to 11 kgf/cm², the temperature for pressing is preferably from 70 to 140° C., the time for pressing is preferably from 15 seconds to 3 minutes, and lamination is performed under a reduced pressure at a pneumatic pressure of 20 mmHg or less. The lamination method may be of either a batch-wise manner or a continuous manner using a roll.

The release film having a support of the present invention is especially useful in the production of a coreless substrate, and an example of the production has the following steps.

(1) The release film having a support is laminated onto a substrate, and then cooled to about room temperature and the support is peeled off the release film.

(2) A metal foil is laminated onto the release film, and further a build-up layer is formed on the metal foil, and the build-up layer is cured to form a build-up insulating layer. Suitable metals for the metal foil include copper, aluminum, gold, platinum, silver, cobalt, chrome, nickel, titanium, tungsten, iron, tin, indium, and the like. Additionally, the surface of the metal foil may be treated with a chromate treatment, a nickel treatment, or a gold treatment. Conditions for the heat treatment for curing of the build-up layer are selected so that the temperature is in the range of from 150 to 220° C. and the time is in the range of from 20 to 180 minutes, and preferred conditions are such that the temperature is in the range of from 160 to 200° C. and the time is in the range of from 30 to 120 minutes. After the heating treatment for curing, the metal foil must be fixed to the substrate all during the fabrication of a circuit board including via formation, plating, etching, and the like, and therefore the resin composition for use in release film after subjected to heating treatment for curing preferably exhibits a bond strength with respect to a metal foil of 0.25 kgf/cm or more, more preferably 0.27 kgf/cm or more, further preferably 0.3 kgf/cm or more, and still further preferably 0.33 kgf/cm or more.

(3) A via is formed in the build-up insulating layer, and the resultant layer is subjected to plating, etching, and the like to form a circuit board. A build-up layer is further formed if necessary.

(4) After a circuit board is formed, a heating treatment for releasing is performed to peel the metal foil off the resin composition for use in release film. It is necessary that the temperature for the heating treatment for releasing be the curing temperature for the build-up insulating layer or higher, and as an example of the heating treatment, there can be mentioned a reflow treatment. The temperature for the heating treatment for releasing is selected from the range of from 220 to 300° C., preferably the range of from 230 to 290° C., and more preferably the range of from 240 to 280° C. The time for the heating treatment for releasing is selected from the range of from 1 to 30 minutes, preferably the range of from 1 to 25 minutes, more preferably the range of from 1 to 20 minutes, further preferably the range of from 2 to 20 minutes, still further preferably the range of from 3 to 15 minutes, and especially preferably the range of from 3 to 10 minutes. After the heating treatment for releasing, the metal foil must be easily peeled off, and therefore the resin composition for use in release film after subjected to heating treatment for releasing preferably exhibits a peel strength with respect to a metal foil of 0.2 kgf/cm or less, more preferably 0.1 kgf/cm or less, further preferably 0.08 kgf/cm or less, still further preferably 0.07 kgf/cm or less, and especially preferably 0.06 kgf/cm or less.

Other features of the invention will become apparent in the course of the following descriptions of exemplary embodiments which are given for illustration of the invention and are not intended to be limiting thereof.

### EXAMPLES

In the following Examples, “part(s)” means “part(s) by mass”.

First, measurement methods and evaluation methods used in the evaluation of physical properties in the present specification are described below.

Measurement and Evaluation of the Bond Strength after Thermal History 1 (Heating Treatment 1 for Curing).

The release films having a support obtained in Examples and Comparative Examples below were individually laminated onto an S surface of a copper foil (JTC foil, manufactured by Nippon Mining & Metals Co., Ltd.) using a vacuum laminator, manufactured by Meiki Co., Ltd., under conditions at a temperature of 100° C., a pressure of 7 kgf/cm², and an atmospheric pressure of 5 mmHg or less to prepare a three-layer laminate comprising copper foil/resin composition layer/PET film. Then, the PET film was peeled off, and the resin composition layer was laminated onto a copper-clad laminate, which had been treated with MEC etch BOND CZ-8100 (surface treatment agent containing a copper complex of an azole and an organic acid), in the same manner as mentioned above. Then, the resin composition layer was subjected to heating treatment at 180° C. for 90 minutes once (thermal history 1) to obtain an evaluation substrate 1. The obtained evaluation substrate 1 was cut into a 150×30 mm specimen, and a notch having a width of 10 mm and a length of 100 mm was formed in the specimen at a copper foil portion, and one end of the copper foil was peeled and held by a fixture, and peeled off 35 mm in the vertical direction at a speed of 50 mm/minute using an Instron universal tester at room temperature. A peeling strength was measured in accordance with the method described in JIS C6481, and defined as a bond strength (kgf/cm) after the thermal history 1 (which corresponds to an experience of being subjected to heating treatment at 180° C. for 90 minutes once). A specimen having a bond strength of less than 0.5 kgf/cm was rated “Δ”, a specimen having a bond strength of 0.5 to less than 0.6 kgf/cm was rated “O”, and a specimen having a bond strength of 0.6 kgf/cm or more was rated “⊙”.

Measurement and Evaluation of the Bond Strength after Thermal History 2 (Heating Treatment 2 for Curing).

The evaluation substrate 1 was further subjected to heating treatment at 180° C. for 90 minutes four times to obtain an evaluation substrate 2. With respect to the obtained evaluation substrate 2, a peeling strength was measured in accordance with the method described in JIS C6481 in the same manner as mentioned above, and defined as a bond strength (kgf/cm) after a thermal history 2 (which corresponds to an experience of being subjected to heating treatment at 180° C. for 90 minutes five times in total). A specimen having a bond strength of more than 0.2 kgf/cm was rated “O”. A specimen in which a blister was caused between the copper foil and the insulating layer after the heat treatment for curing was rated “x”.

Measurement and Evaluation of the Peel Strength after Thermal History 3 (Heating Treatment for Releasing).

The evaluation substrate 2 was further subjected to heating treatment at 270° C. for 55 seconds five times using a reflow furnace to obtain an evaluation substrate 3. With respect to the obtained evaluation substrate 3, a peeling strength was measured in accordance with the method described in JIS C6481 in the same manner as mentioned above, and defined as a peel strength (kgf/cm) after a thermal history 3 (which corresponds to an experience of being subjected to both heating treatment at 180° C. for 90 minutes five times and heating treatment at 270° C. for 55 seconds five times). A specimen having a peel strength of less than 0.1 kgf/cm was rated “O”, a specimen having a peel strength of 0.1 to less than 0.2 kgf/cm was rated “Δ”, and a specimen having a peel strength of 0.2 kgf/cm or more was rated “x”.

### Evaluation of the Appearance for Releasability.

With respect to the specimen of evaluation substrate 3 which had been subjected to measurement of the peel strength after the thermal history 3 (heating treatment for releasing), the surface of the peeled copper foil was visually observed. A specimen such that a small amount of the resin remained on the copper foil was rated “Δ”, a specimen such that almost no resin remained on the copper foil was rated “O”, and a specimen such that no resin remained on the copper foil was rated “⊙”.

### Preparation Example 1

### Preparation of a Polyimide Resin (Modified Polyimide Resin Varnish A)

In a reaction vessel, 50 g of G-3000 (difunctional hydroxyl-terminal polybutadiene; number average molecular weight=5,047 (GPC method); hydroxyl equivalent=1,798 g/eq.; solids content: 100 wt %; manufactured by Nippon Soda Co., Ltd.), 23.5 g of Ipzole 150 (aromatic hydrocarbon mixed solvent; manufactured by Idemitsu Petrochemical Co., Ltd.), and 0.005 g of dibutyltin dilaurate were mixed together and uniformly dissolved. After a uniform solution was obtained, the temperature of the solution was elevated to 50° C., and while stirring, 4.8 g of toluene-2,4-diisocyanate (isocyanate equivalent=87.08 g/eq.) was added to the solution to effect a reaction for about 3 hours. Then, the resultant reaction mixture was cooled to room temperature, and to the cooled mixture were added 8.96 g of benzophenonetetracarboxylic dianhydride (acid anhydride equivalent=161.1 g/eq.), 0.07 g of triethylenediamine, and 40.4 g of ethyl diglycol acetate (manufactured by Daicel Chemical Industries, Ltd.), and the resultant mixture was heated to 130° C. while stirring to effect a reaction for about 4 hours. By an FT-IR analysis, the disappearance of an NCO peak at 2,250 cm⁻¹ was confirmed. The confirmation of the disappearance of NCO peak was regarded as the termination of the reaction, and the resultant reaction mixture was cooled to room temperature and subjected to filtration using a 100-mesh filter cloth to obtain a modified polyimide resin (modified polyimide resin varnish A). Properties of the modified polyimide resin varnish A: viscosity=7.5 Pa·s (25° C., E type viscometer); acid value=16.9 mg KOH/g; solids content=50 wt %; number average molecular weight=13,723; polybutadiene structure portion content=50×100/(50+4.8+8.96)=78.4% by mass.

### Example 1

4 Parts of a liquid bisphenol A epoxy resin (epoxy equivalent: 180; “jER 828EL”, manufactured by Mitsubishi Chemical Corporation), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 37 parts of aluminum hydroxide (“H-43S”, manufactured by Showa Denko K.K.; average particle size: 0.7 μm) were mixed together and uniformly dispersed by means of a high-speed rotary mixer to prepare a resin varnish. Then, the prepared resin varnish was applied to polyethylene terephthalate film (thickness: 38 μm; hereinafter, referred to simply as “PET”) using a die coater so that the thickness of the dried resin composition became 40 μm, and dried at 80 to 120° C. (average: 100° C.) for 7 minutes (residual solvent amount: about 2% by mass). Then, the PET film having the resin composition applied was wound into a roll form while attaching a polypropylene film having a thickness of 15 μm to the surface of the resin composition layer. The roll-form release film having a support was slit into a width of 507 mm to obtain a sheet-form release film having a support and having a size of 507 mm×336 mm.

### Example 2

4 Parts of a liquid bisphenol A epoxy resin (epoxy equivalent: 180; “jER 828EL”, manufactured by Mitsubishi Chemical Corporation), 1 part of a phenolic novolak resin (phenolic hydroxyl equivalent: 105; MEK solution of “TD 2090”, manufactured by DIC Corporation, having a solids content of 60% by mass), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 37 parts of aluminum hydroxide (“H-43S”, manufactured by Showa Denko K.K.; average particle size: 0.7 μm) were mixed together and uniformly dispersed by means of a high-speed rotary mixer to prepare a resin varnish. Then, a release film having a support was obtained in the same manner as in Example 1.

### Example 3

4 Parts of a liquid bisphenol A epoxy resin (epoxy equivalent: 180; “jER 828EL”, manufactured by Mitsubishi Chemical Corporation), 4 parts of a phenolic novolak resin (phenolic hydroxyl equivalent: 105; MEK solution of “TD 2090”, manufactured by DIC Corporation, having a non-volatile content of 60% by mass), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 37 parts of aluminum hydroxide (“H-43S”, manufactured by Showa Denko K.K.; average particle size: 0.7 μm) were mixed together and uniformly dispersed by means of a high-speed rotary mixer to prepare a resin varnish. Then, a release film having a support was obtained in the same manner as in Example 1.

### Example 4

4 Parts of a liquid bisphenol A epoxy resin (epoxy equivalent: 180; “jER 828EL”, manufactured by Mitsubishi Chemical Corporation), 1 part of a phenolic novolak resin (phenolic hydroxyl equivalent: 105; MEK solution of “TD 2090”, manufactured by DIC Corporation, having a non-volatile content of 60% by mass), 0.1 part of an imidazole cure accelerator (“2P4 MZ”, manufactured by Shikoku Chemicals Corporation), 60 parts of a modified polyimide resin varnish A, 20 parts of MEK, 6.8 parts of a dicyclopentadiene epoxy resin (epoxy equivalent: 280; “HP 7200H”, manufactured by DIC Corporation), and 37 parts of aluminum hydroxide (“H-43S”, manufactured by Showa Denko K.K.; average particle size: 0.7 μm) were mixed together and uniformly dispersed by means of a high-speed rotary mixer to prepare a resin varnish. Then, a release film having a support was obtained in the same manner as in Example 1.

### Example 5

4 Parts of a liquid bisphenol A epoxy resin (epoxy equivalent: 180; “jER 828EL”, manufactured by Mitsubishi Chemical Corporation), 1 part of a phenolic novolak resin (phenolic hydroxyl equivalent: 105; MEK solution of “TD 2090”, manufactured by DIC Corporation, having a non-volatile content of 60% by mass), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 37 parts of aluminum hydroxide (“CL-301R”, manufactured by Sumitomo Chemical Co., Ltd.; average particle size: 1.5 μm) were mixed together and uniformly dispersed by means of a high-speed rotary mixer to prepare a resin varnish. Then, a release film having a support was obtained in the same manner as in Example 1.

### Example 6

4 Parts of a liquid bisphenol A epoxy resin (epoxy equivalent: 180; “jER 828EL”, manufactured by Mitsubishi Chemical Corporation), 1 part of a triazine structure-containing phenolic novolak resin (phenolic hydroxyl equivalent: 125; MEK solution of “PHENOLITE LA 7054”, manufactured by DIC Corporation, having a non-volatile content of 60% by mass), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 37 parts of aluminum hydroxide (“H-43S”, manufactured by Showa Denko K.K.; average particle size: 0.7 μm) were mixed together and uniformly dispersed by means of a high-speed rotary mixer to prepare a resin varnish. Then, a release film having a support was obtained in the same manner as in Example 1.

### Example 7

4 Parts of a liquid bisphenol A epoxy resin (epoxy equivalent: 180; “jER 828EL”, manufactured by Mitsubishi Chemical Corporation), 0.1 part of an imidazole cure accelerator (“2P4 MZ”, manufactured by Shikoku Chemicals Corporation), 10 parts of MEK, 6.8 parts of a dicyclopentadiene epoxy resin (epoxy equivalent: 280; “HP 7200H”, manufactured by DIC Corporation), and 37 parts of aluminum hydroxide (“H-43S”, manufactured by Showa Denko K.K.; average particle size: 0.7 μm) were mixed together and uniformly dispersed by means of a high-speed rotary mixer to prepare a resin varnish. Then, a release film having a support was obtained in the same manner as in Example 1.

### Example 8

4 Parts of a liquid bisphenol A epoxy resin (epoxy equivalent: 180; “jER 828EL”, manufactured by Mitsubishi Chemical Corporation), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 18 parts of aluminum hydroxide (“H-43S”, manufactured by Showa Denko K.K.; average particle size: 0.7 μm) were mixed together and uniformly dispersed by means of a high-speed rotary mixer to prepare a resin varnish. Then, a release film having a support was obtained in the same manner as in Example 1.

### Example 9

4 Parts of a liquid bisphenol A epoxy resin (epoxy equivalent: 180; “jER 828EL”, manufactured by Mitsubishi Chemical Corporation), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 56 parts of aluminum hydroxide (“H-43S”, manufactured by Showa Denko K.K.; average particle size: 0.7 μm) were mixed together and uniformly dispersed by means of a high-speed rotary mixer to prepare a resin varnish. Then, a release film having a support was obtained in the same manner as in Example 1.

### Example 10

4 Parts of a liquid bisphenol A epoxy resin (epoxy equivalent: 180; “jER 828EL”, manufactured by Mitsubishi Chemical Corporation), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), 18.5 parts of aluminum hydroxide (“H-43S”, manufactured by Showa Denko K.K.; average particle size: 0.7 μm), and 18.5 parts of spherical silica (“SO-C2”, manufactured by Admatechs Co., Ltd.; average particle size: 0.5 μm) were mixed together and uniformly dispersed by means of a high-speed rotary mixer to prepare a resin varnish. Then, a release film having a support was obtained in the same manner as in Example 1.

### Comparative Example 1

4 Parts of a liquid bisphenol A epoxy resin (epoxy equivalent: 180; “jER 828EL”, manufactured by Mitsubishi Chemical Corporation), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 37 parts of magnesium hydroxide (“KISUMA 5”, manufactured by Kyowa Chemical Industry Co., Ltd.; average particle size: 0.6 to 1.0 μm) were mixed together and uniformly dispersed by means of a high-speed rotary mixer to prepare a resin varnish. Then, a release film having a support was obtained in the same manner as in Example 1.

### Comparative Example 2

4 Parts of a liquid bisphenol A epoxy resin (epoxy equivalent: 180; “jER 828EL”, manufactured by Mitsubishi Chemical Corporation), 1 part of a phenolic novolak resin (phenolic hydroxyl equivalent: 105; MEK varnish of “TD 2090”, manufactured by DIC Corporation, having a non-volatile content of 60% by mass), 0.1 part of an imidazole cure accelerator (“2P4 MZ”, manufactured by Shikoku Chemicals Corporation), 40 parts of a modified polyimide resin varnish A, 20 parts of MEK, 6.8 parts of a dicyclopentadiene epoxy resin (epoxy equivalent: 280; “HP 7200H”, manufactured by DIC Corporation), and 35 parts of spherical silica (“SO-C2”, manufactured by Admatechs Co., Ltd.; average particle size: 0.5 μm) were mixed together and uniformly dispersed by means of a high-speed rotary mixer to prepare a resin composition varnish. Then, an adhesive film was obtained in the same manner as in Example 1.

### Comparative Example 3

2 Parts of a liquid bisphenol A epoxy resin (epoxy equivalent: 180; “jER 828EL”, manufactured by Mitsubishi Chemical Corporation), 2 parts of a phenolic novolak resin (phenolic hydroxyl equivalent: 105; MEK varnish of “TD 2090”, manufactured by DIC Corporation, having a non-volatile content of 60% by mass), 0.1 part of an imidazole cure accelerator (“2P4 MZ”, manufactured by Shikoku Chemicals Corporation), 20 parts of a modified polyimide resin varnish A, 20 parts of MEK, 2.6 parts of a dicyclopentadiene epoxy resin (epoxy equivalent: 280; “HP 7200H”, manufactured by DIC Corporation), and 15 parts of spherical silica (“SO-C2”, manufactured by Admatechs Co., Ltd.; average particle size: 0.5 μm) were mixed together and uniformly dispersed by means of a high-speed rotary mixer to prepare a resin composition varnish. Then, an adhesive film was obtained in the same manner as in Example 1.

The results of measurements are shown in Table 1.

TABLE 1

| In terms of non-volatile | | | | | | | | | | | | | | |
|---|---|---|---|---|---|---|---|---|---|---|---|---|---|---|
| content | | | | | | | | | | | | Comp. | Comp. | Comp. |
| {Part(s) by mass} | | Ex. 1 | Ex. 2 | Ex. 3 | Ex. 4 | Ex. 5 | Ex. 6 | Ex. 7 | Ex. 8 | Ex. 9 | Ex. 10 | Ex. 1 | Ex. 2 | Ex. 3 |
| (A) Epoxy | jER 828EL | 4 | 4 | 4 | 4 | 4 | 4 | 4 | 4 | 4 | 4 | 4 | 4 | 2 |
| resin | HP 7200H | 6.8 | 6.8 | 6.8 | 6.8 | 6.8 | 6.8 | 6.8 | 6.8 | 6.8 | 6.8 | 6.8 | 6.8 | 2.6 |
| (B) | H-43S | 37 | 37 | 37 | 37 | | 37 | 37 | 18 | 56 | 18.5 | | | |
| Aluminum | CL 301R | | | | | 37 | | | | | | | | |
| hydroxide | | | | | | | | | | | | | | |
| (C) Curing | TD 2090 | | 0.6 | 2.4 | 0.6 | 0.6 | | | | | | | 0.6 | 1.2 |
| agent | LA 7054 | | | | | | 0.6 | | | | | | | |
| (D) | Modified | 20 | 20 | 20 | 30 | 20 | 20 | | 20 | 20 | 20 | 20 | 20 | 10 |
| Thermo- | polyimide | | | | | | | | | | | | | |
| plastic | resin | | | | | | | | | | | | | |
| resin | varnish A | | | | | | | | | | | | | |
| (E) Cure | 2P4 MZ | 0.1 | 0.1 | 0.1 | 0.1 | 0.1 | 0.1 | 0.1 | 0.1 | 0.1 | 0.1 | 0.1 | 0.1 | 0.1 |
| accelerator | | | | | | | | | | | | | | |
| Magne- | KISUMA | | | | | | | | | | | 37 | | |
| sium | 5 | | | | | | | | | | | | | |
| hydroxide | | | | | | | | | | | | | | |
| Spherical | SO-C2 | | | | | | | | | | 18.5 | | 35 | 15 |
| silica | | | | | | | | | | | | | | |

| | | | | | | | | | | | | | |
|---|---|---|---|---|---|---|---|---|---|---|---|---|---|
| Content of (A) | 15.91 | 15.77 | 15.36 | 13.76 | 15.77 | 15.77 | 22.55 | 22.09 | 12.43 | 15.91 | 15.91 | 16.24 | 14.89 |
| Epoxy resin | | | | | | | | | | | | | |
| Content of (B) | 54.49 | 54.01 | 52.63 | 47.13 | 54.01 | 54.01 | 77.24 | 36.81 | 64.44 | 27.25 | 0.00 | 0.00 | 0.00 |
| Aluminum hydroxide | | | | | | | | | | | | | |
| Reactive functional | 0 | 0.12 | 0.49 | 0.12 | 0.12 | 0.12 | 0 | 0 | 0 | 0 | 0 | 0.12 | 0.54 |
| group number of (C) | | | | | | | | | | | | | |
| Curing agent/ | | | | | | | | | | | | | |
| Epoxy group number | | | | | | | | | | | | | |
| of (A) Epoxy resin | | | | | | | | | | | | | |
| Bond strength | ◯ | ◯ | ◯ | ◯ | ⊙ | ◯ | ◯ | ⊙ | ◯ | ⊙ | ⊙ | ⊙ | ⊙ |
| (kgf/cm) after | (0.59) | (0.54) | (0.57) | (0.56) | (0.63) | (0.5) | (0.55) | (0.73) | (0.5) | (0.6) | (0.6) | (0.63) | (0.63) |
| thermal history 1 | | | | | | | | | | | | | |
| Bond strength | ◯ | ◯ | ◯ | ◯ | ◯ | ◯ | ◯ | ◯ | ◯ | ◯ | ◯ | ◯ | ◯ |
| (kgf/cm) after | (0.35) | (0.37) | (0.39) | (0.35) | (0.41) | (0.35) | (0.35) | (0.59) | (0.3) | (0.4) | (0.41) | (0.41) | (0.50) |
| thermal history 2 | | | | | | | | | | | | | |
| Peel strength | ◯ | ◯ | ◯ | ◯ | ◯ | ◯ | ◯ | ◯ | ◯ | ◯ | X | X | X |
| (kgf/cm) after | (0.05) | (0.02) | (0.04) | (0.02) | (0.03) | (0.02) | (0.05) | (0.05) | (0.04) | (0.04) | (0.37) | (0.33) | (0.43) |
| thermal history 3 | | | | | | | | | | | | | |
| Evaluation of | ◯ | ◯ | ◯ | ⊙ | ◯ | ◯ | Δ | ◯ | ◯ | ◯ | ◯ | ◯ | ◯ |
| appearance | | | | | | | | | | | | | |
| for releasability | | | | | | | | | | | | | |

From the results shown in Table 1 above, it is seen that each of the release films having a support obtained in Examples 1 to 10 retains a high bond strength after the thermal history 2 and has excellent releasability after subjected to heating treatment for releasing. It has been found that, on the other hand, the adhesive films obtained in Comparative Examples 1 to 3 individually exhibit a large peel strength after the thermal history 3 so that they cannot be used as a release film.

### INDUSTRIAL APPLICABILITY

By incorporating an epoxy resin and aluminum hydroxide into a resin composition, there can be provided a resin composition for use in a release film and a release film, which retain high bond strength after a build-up layer is cured, and which have excellent peel strength after subjected to heating treatment for releasing. Further, these can be used to provide electric products, such as computers, mobile phones, digital cameras, and televisions, and vehicles, such as motorcycles, automobiles, trains, ships, and airplanes, and they are of great commercial significance.

Where a numerical limit or range is stated herein, the endpoints are included. Also, all values and subranges within a numerical limit or range are specifically included as if explicitly written out.

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

1. A resin composition, comprising (A) at least one epoxy resin and (B) aluminum hydroxide.

2. A resin composition according to claim 1, which exhibits a bond strength of 0.25 kgf/cm or more with respect to a metal foil after having been subjected to heating treatment at 180° C. for 90 minutes five times, and exhibits a peel strength of 0.2 kgf/cm or less with respect to a metal foil after having been further subjected to heating treatment at 270° C. for 55 seconds five times.

3. A resin composition according to claim 1, which exhibits a bond strength of 0.25 kgf/cm or more with respect to a metal foil after having been subjected to heating treatment at 180° C. for 90 minutes five times, and exhibits a peel strength of 0.07 kgf/cm or less with respect to a metal foil after having been further subjected to heating treatment at 270° C. for 55 seconds five times.

4. A resin composition according to claim 1, which comprises aluminum hydroxide (B) in an amount of 5 to 85% by mass per 100% by mass of the non-volatile component in said resin composition.

5. A resin composition according to claim 1, wherein said aluminum hydroxide (B) has an average particle size of from 0.01 to 5 μm.

6. A resin composition according to claim 1, further comprising (C) at least one curing agent.

7. A resin composition according to claim 6, which comprises a phenolic curing agent.

8. A resin composition according to claim 6, wherein when the epoxy group number of said epoxy resin (A) is taken as 1, the reactive functional group number of said curing agent (C) is from 0.05 to 1.

9. A resin composition according to claim 1, further comprising (D) at least one thermoplastic resin.

10. A resin composition according to claim 9, which comprises at least one modified polyimide resin.

11. A resin composition according to claim 10, wherein said at least one modified polyimide resin has in the molecule thereof a polybutadiene structure, an urethane structure, and an imide structure.

12. A resin composition according to claim 1, further comprising (E) at least one cure accelerator.

13. A release film, comprising a resin composition according to claim 1.

14. A release film having a support, comprising a resin composition according to claim 1 and a support.

15. A method for preparing a circuit board, comprising:
(1) laminating a release film according to claim 14 onto a substrate, such that the resin composition is between said support and said substrate;
(2) removing said support from said release film, to expose a surface of said resin composition;
(3) laminating a metal foil onto said exposed surface of said resin composition;
(4) forming a circuit board the surface of said metal film opposite the surface laminated to said resin composition, to obtain an assembly comprising said support, said resin composition, and said circuit board; and
(5) removing said resin composition from said metal film.

16. A method according to claim 15, further comprising:
(4′) heating said assembly after said forming said circuit board and before said removing said resin composition.

17. A method according to claim 16, wherein said heating is conducted at a temperature of from 220 to 300° C. for a time of from 1 to 30 minutes.

18. A method according to claim 16, wherein said heating is conducted at a temperature of from 240 to 280° C. for a time of from 1 to 25 minutes.

19. A circuit board, which is prepared by a process according to claim 15.

20. A circuit board, which is prepared by a process according to claim 16.
